(19) United States
(12) Patent Application Publication
(10) Pub. No.: US 2004/0092102 A1
(43) Pub. Date: May 13, 2004

(54) Chemical mechanical polishing composition and method

(75) Inventors: Yuzhou Li, Norwood, NY (US); Jason Keleher, Schenectady, NY (US); Junzi Zhao, Potsdam, NY (US); Chris Brancewicz, Potsdam, NY (US)

Correspondence Address: VINSON & ELKINS, L.L.P., 1001 FANNIN STREET, 2300 FIRST CITY TOWER, HOUSTON, TX, 77002-6760, US

(73) Assignee: Sachem, Inc.

(21) Appl. No.: 10/292,404

(22) Filed: Nov. 12, 2002

(51) Int. Cl. C09K 3/14; H01L 21/302; H01L 21/461

(52) U.S. Cl. 438/689

(57) ABSTRACT

A chemical mechanical polishing (CMP) formulation and method for using the same. The composition is useful for polishing semiconductor substrates, and particularly substrate surfaces containing copper, tungsten, or alloys of the same. The CMP formulation may contain a copolymer enhancement agent such as a Pluronics® compound, and/or a vesicle encapsulating agent, as well as an active agent that is chemically reactive with the substrate to enhance polishing performance. The active agent may be a bifunctional compound that is capable of functioning as both a passivating agent and a complexing agent to achieve an optimum rate of passivation and oxidation on the substrate surface. An active agent can also take the form of an oxidation activator, such as a metal ion, encapsulated in a vesicle or micelle, that is released with applied pressure to accelerate the removal process and improve planarization efficiency.

### FIELD OF THE INVENTION

The present invention generally relates to a chemical mechanical polishing (“CMP”) composition for semiconductor device planarization. The present invention is particularly useful for polishing metal layers on semiconductor wafers.

### BACKGROUND OF THE INVENTION

In microchip fabrication, integrated circuits are formed on a semiconducting substrate such as a silicon wafer. The integrated circuits are typically chemically and physically integrated into the substrate by patterning regions into the substrate and layers onto the substrate. The layers are formed of various materials that have either a conductive, insulating, or semiconducting nature. These materials can be patterned, doped with impurities, and deposited by various processes to form the integrated circuits. Active devices (e.g., transistors, diodes, etc.) formed on the substrate are interconnected via metal lines embedded in a dielectric layer (i.e., “interconnects”).

As silicon technology has advanced to ultra large scale integration (ULSI), the devices on silicon wafers have shrunk to sub-micron dimensions and the circuit density has increased to several million transistors per die. These diminishing geometries have necessitated improved deposition and patterning techniques during the manufacture of semiconductor devices. As an example, dielectric layers formed over interlevel conducting lines are typically planarized to minimize topographic effects on subsequent photolithography processes. In a typical process, a dielectric layer is deposited over patterned metal or semiconductor lines in such a way as to fill in the gaps between the lines. The dielectric deposition can be followed by a planarization step such as chemical mechanical planarization to remove excess material and planarize the surface topography.

Chemical mechanical polishing is a process that is used to planarize semiconductor wafers by using physical and chemical mechanisms for polishing. In general, the CMP process involves holding a semiconductor substrate, such as a wafer, against a rotating wetted polishing pad under a controlled downward pressure. A rotating polishing head or wafer carrier is typically utilized to hold the wafer in place against the polishing pad. Both the pad and wafer are then counter-rotated while a CMP slurry, which typically contains surface-modifying chemical components and an abrasive material such as alumina or silica particles, is passed between them. The wafer is chemically modified and then abraded by the polishing force exerted by the polishing pad. The abraded material is then removed from the wafer surface due to the solution flow and pad rotation. The polishing pad is typically formed of a relatively soft wetted pad material such as a felt fiber fabric impregnated with blown polyurethane.

The goal of CMP is to obtain uniform planarization globally across the wafer. Planarization occurs when the interconnects are polished to the point where both the interconnects and the surrounding areas of the substrate are at the same level. Some of the more significant problems that can arise during CMP are dishing, erosion, and corrosion. Dishing and erosion are forms of local non-planarity that arise when uneven material removal rates occur across the wafer. FIG. 1 depicts a silicon wafer surface containing a copper (Cu) interconnect line that has undergone dishing and erosion. Dishing occurs when a portion of material is “dished” out of (i.e., removed from) the wafer surface. On the other hand, erosion occurs when a whole section of a die is polished faster than surrounding areas. Corrosion occurs when pits, fractures, or depressions are formed in a wafer surface due to chemical attack from the polishing slurry. Additional background information on CMP can be found in U.S. Pat. No. 6,313,039 B1 to Small et al. and U.S. Pat. No. 6,362,106 Bi to Kaufinan et al., each of which are incorporated by reference as if fully set forth herein.

### SUMMARY OF THE INVENTION

The present invention provides an improved CMP polishing formulation and method for polishing a semiconductor substrate that facilitates improved polishing performance and planarization efficiency while minimizing or eliminating dishing, erosion, corrosion, scratches, and other defects.

In one embodiment of the invention, the CMP formulation includes water, an effective amount of an oxidizing agent, and a copolymer for enhancing polishing performance. The oxidizing agent is useful for facilitating polishing by promoting the removal of material from the substrate. The copolymer preferably includes a first unit having a hydrophilic nature and a second unit having a hydrophobic nature that is located substantially adjacent to the first unit. The formulation may also contain a bifunctional compound having a first functional group capable of inhibiting corrosion on the substrate and a second functional group capable of forming a complex with material abraded from the substrate that is capable of catalyzing decomposition of the oxidizing agent to form a stronger oxidizer.

In another embodiment of the invention, the CMP formulation includes an active agent that is chemically reactive to enhance polishing and a supramolecular structure that is capable of substantially isolating the active agent in the formulation and then subsequently releasing the reactive agent in response to a force applied against the substrate during polishing. The supramolecular structure can be a micelle for solubilizing the active agent or a vesicle, liposome, or other encapsulant for encapsulating the active agent. The active agent may be an oxidizing agent, excess metal ions, a passivating agent, a complexing agent, or a bifunctional agent.

In yet another embodiment, a liposome encapsulant is made by first mixing phospholipids, water, and a hydrotrope to form a stock solution. A second solution containing an active agent such as metal ions is added to the stock solution to promote the formation of vesicles, and the resulting solution is agitated to promote the encapsulation of the active agent within the vesicles. An oxidizing agent is also added to the solution.

A semiconductor substrate can be polished by applying the CMP composition to the substrate and applying a polishing force to the substrate. An encapsulant in the formulation preferably forms a core that contains active agent. Alternatively, a micelle can be formed in the composition to solubilize the active agent and isolate it from the substrate or other ingredients in the solution. The forces applied to the substrate by the polishing action of the polishing pad preferably disturb or rupture the micelle or encapsulant to release the active agent, which causes a chemical reaction that enhances polishing performance. The active agent is preferably released predominantly from encapsulants or micelles that are located near the protruding regions of the substrate to enhance planarization efficiency.

Definitions

The detailed description and appended claims should be construed in light of the following definitions:

An “oxidizing agent” is any agent capable of oxidizing a wafer surface to facilitate the removal of material from the surface. The term “oxidizing agent” includes compounds such as hydrogen peroxide that decompose to form other oxidizing agents (e.g., free radicals). Non-limiting examples of “oxidizing agents” include hydrogen peroxide, urea-hydrogen peroxide, potassium persulfate, ammonium persulfate, hydroxyl radicals, free radicals, peroxides, alkyl hydroperoxides, persulfates, periodates, chlorates, perchlorates, nitrates, and permanganates.

A “passivating agent” or “corrosion inhibitor” is any compound that is capable of inhibiting corrosion on a substrate surface or forming an oxide layer on a metal surface.

A “complexing agent” is any compound that is capable of forming a complex with a metal surface or with particles that have been abraded from a substrate surface. Examples of a “complexing agent” include (but are not limited to) proline, glycine, and tryptophan.

A “bifunctional agent” is a molecule that has two or more functional groups and that is capable of (i) forming a complex with a metal, and (ii) catalyzing the decomposition of an oxidizing agent. Examples of “bifunctional agents” include (but are not limited to) imidazoles, bipyridine and substituted bipyridines, substituted pyridines, and aryl amines.

A “copolymer” is a large molecule whose structure depends upon two or more different monomers used in its production.

A “micelle” is a colloidal aggregate of molecules that spontaneously forms at or above a defined concentration of the molecules known as the “critical micellization concentration.”

A “vesicle” is a substantially spherical aggregate of molecules that encapsulates part of the solvent (and any dissolved species therein) that it is formed in.

A “liposome” is vesicle that is made up of one or more lipid bilayers.

A “hydrotrope” is a water soluble amphiphilic molecule that lacks sufficient lipophilicity to act as a surfactant.

A “supramolecular structure” is any structure made up of numerous molecules that is capable of reversibly separating, isolating, or solubilizing an active agent in the CMP formulation. Non-limiting examples of supramolecular structures include micelles, vesicles, liposomes, and other encapsulants.

An “encapsulant” is any structure that forms a core within which an active agent can be reversibly trapped or encapsulated. Non-limiting examples of encapsulants include vesicles, liposomes, and polymeric shells.

A “cosolvent” is any compound other than water that is capable of increasing the solubility of another compound contained in the CMP formulation.

A “pH adjustment agent” is any compound that is useful for altering the pH of the CMP formulation.

An “active agent” is any compound that is chemically reactive with the substrate or any other ingredient in the formulation to increase the material removal rate or enhance overall polishing performance. Non-limiting examples of active agents are oxidizing agents, passivating agents, complexing agents, bifunctional compounds, and excess metal ions.

A “radical quencher” is any compound that is reactive with a free radical to reduce or eliminate the oxidizing power of the free radical.

### BRIEF DESCRIPTION OF THE DRAWINGS

FIG. 1 depicts a silicon wafer surface containing a copper (Cu) interconnect line that has undergone dishing and erosion.

FIG. 2 pictorially depicts two functional groups in an exemplary bifunctional compound.

FIGS. 3A to 3S depict examples of some benzimidazole-based derivatives suitable for use as bifunctional agents.

FIGS. 4A to 4Q depict examples of some bipyridal-based derivatives suitable for use as bifunctional agents.

FIG. 5 depicts an intelligent abrasive-free system that includes H₂O₂ oxidizer, a reactive complex, and a supramolecular structure.

FIG. 6 provides a table summarizing some physical properties of various Pluronic® compounds.

FIG. 7 provides a table of the ACR and LAC values for some exemplary Pluronic® compounds.

FIG. 8A depicts a liposome composed of a lipid bilayer.

FIG. 8B depicts a lipid.

FIG. 9 pictorially depicts copper ions encapsulated within a liposome.

FIG. 10 contains a chart summarizing the material removal rates and static etch rates that were achieved using four exemplary AF Cu CMP formulations to polish a 1 inch copper disk.

FIG. 11 contains a graph showing the results of a solubility study to investigate the presence of micelles in a CMP formulation that contains benzimidazole (BIA).

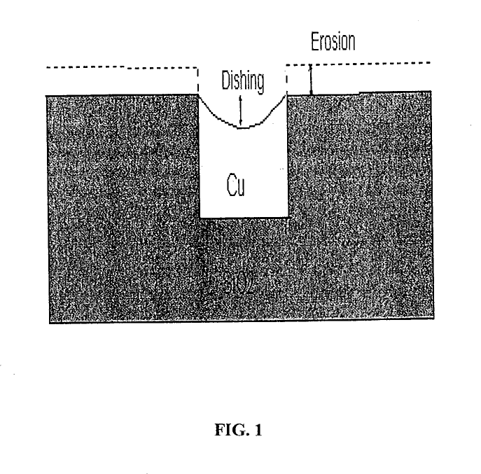

### DETAILED DESCRIPTION OF THE INVENTION

The present invention relates to an improved CMP polishing formulation that is useful for polishing metal-containing layers present on a semiconductor substrate such as a wafer, an integrated circuit, a thin film, a multiple level semiconductor, etc. The CMP formulations of the present invention are useful for polishing materials that include, e.g., metals, interlayer dielectric (“ILD”) material (e.g., silicon oxide, low-k materials, etc.), and structures such as shallow trench isolation (“STI”) materials. Various embodiments of the present invention have been found to be particularly effective for CMP of copper layers and copper alloy layers, particularly during the first step of a Cu CMP process and as applied to the Cu Dual Damascene process for oxide and low-k dielectric materials. These formulations are also useful for polishing layers that contain titanium, tantalum, aluminum, and/or tungsten, among other metals.

Various CMP process parameters such as load, slurry flow rate, table speed, quill speed, and polishing pad characteristics (e.g., type, structure, etc.) all tend to affect the material removal rate from the semiconductor substrate. The CMP formulation that is employed also plays a significant role. The incorporation of active chemical agents into a CMP formulation can have a substantial impact on various surface processes that are believed to take place during polishing. Without intending to be bound to any particular theory, it is believed that these surface processes include the following: (i) the formation of a protective surface layer or passivation layer (e.g., metal oxide layer) that inhibits corrosion and protects low-lying areas of the substrate; (ii) dissolution of the abraded metal into the slurry; and (iii) a synergetic enhancement of the material removal rate. The metal oxide film formed on the substrate surface acts as a protection barrier to prevent chemical etching of the metal. It is believed that mechanical forces from abrasive particle and/or the polishing pad can then selectively remove the passive film to permit metal removal at controlled rates.

Various embodiments of the present invention have been found to lessen and/or minimize undesirable dishing and corrosion of the copper lines, microscratches, and erosion of the ILD. These formulations have further been found to be effective on copper-containing substrates without the use of abrasive particles, which reduces the overall process strain and significantly reduces and/or eliminates undesirable dishing and erosion. It is believed that the polishing solution chemically interacts with the metal surface via complexation or direct etch attack while utilizing the abrasive strength of the polishing pad.

The active ingredients in the composition preferably exhibit a weak interaction with the barrier or ILD material and thus generate a high selectivity in removal rate. The composition and method of the present invention tend to reduce and/or eliminate problems such as severe scratching, particle contamination, and slurry instability due to abrasive particle aggregation or settling.

The CMP formulations of the present invention may contain some or all of the following ingredients: (i) an oxidizing agent; (ii) water; (iii) a copolymer; (iv) a passivating agent; (v) a complexing agent; (vi) a bifunctional agent; (vii) a surfactant; (viii) a cosolvent; (ix) a pH adjuster; (x) a radical quencher; (xi) excess metal ions; (xii) abrasive particles; and (xiii) any other optional additives that one of ordinary skill in the art (having the benefit of this description) would recognize as a suitable ingredient in a CMP polishing solution. Additionally, supramolecular structures such as micelles, vesicles, liposomes, etc. may be formed in, or added to, the formulation to increase planarization efficiency. A detailed description of each of these ingredients is set forth below.

In one embodiment of the invention, the CMP formulation includes (i) an oxidizing agent to oxidize the metal on the substrate surface, (ii) water, and (iii) a bifunctional agent that includes at least two functional groups on one molecule to enable it to act as both (a) a passivating agent to aid in forming a protective film on the substrate surface and (b) a catalyst to catalyze the decomposition of the oxidizing agent during polishing.

In another embodiment of the invention, the CMP formulation includes (i) an oxidizing agent to oxidize the metal on the substrate surface, (ii) water, and (iii) a copolymer enhancement agent such as a polyoxyalkylene block copolymer for enhancing polishing performance. The copolymer enhancement agent and the bifunctional agent have been found to have a synergistic effect on polishing performance and efficiency when combined in the same formulation.

In still another embodiment of the invention, the CMP formulation includes (i) an oxidizing agent to oxidize the metal on the substrate surface, (ii) water, (iii) a metal ion for use as a oxidation activator, (iv) a vesicle for encapsulating the metal ion, and (v) an abrasive to assist in the polishing of the surface. One exemplary type of vesicle is formed by combination of lecithin, sodium xylenesulfonate, and water. This solution can be mixed with a metal ion salt to achieve encapsulation of the metal ion within the vesicle.

One exemplary CMP formulation consists of 3% hydrogen peroxide, 0.59% Benzimidazole, 1% Pluronic® P-103, 0.18% hydrochloric acid, and deionized water as the remainder of the formulation to give a pH of about 4.5.

A second exemplary CMP formulation consists of 3% Hydrogen Peroxide, 1% Proline, 1% lecithin vesicle with 135 ppm Copper (II) ion encapsulated therein, and 5% colloidal silica abrasive, with the remainder of the formulation being made up of deionized water and sufficient sulfuric acid to achieve a pH of about 5.8.

A third exemplary CMP formulation consists of the following: 3% Hydrogen Peroxide, 1% Glycine, and 1% lecithin vesicle with 200 ppm Copper (II) ion encapsulated therein, with the remainder of the formulation being made up of deionized water and sufficient sulfuric acid to achieve a pH of about 5.0.

A fourth exemplary CMP formulation consists of the following: 3% Hydrogen Peroxide, 1% Glycine, and 1% lecithin vesicle, with the remainder of the formulation being made up of deionized water and sufficient sulfuric acid to achieve a pH of about 5.8.

Throughout this description various aspects of the invention have been described as discrete embodiments for clarity of explanation. As will be appreciated by those of skill in the art having the benefit of this disclosure, numerous formulations within the scope of this invention may be arrived at by combining various features of the embodiments described herein in whole or in part and as described in the appended claims.

It is to be further understood that any numerical ranges recited herein are taken to include all intermediate values from the lower value to the upper value in increments of one unit provided that there is a separation of at least 2 units between the lowest value and the highest value. As an example, if it is stated that the amount of a component in weight percentage ranges from 1 to 90, preferably from 20 to 80, more preferably from 30 to 70, it is intended that values such as 15 to 85, 22 to 68, 43 to 51, 30 to 32 and the like, are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner. As used herein, parts per million (“ppm”) means milligrams per liter of solution. Finally, all percentages of formulation ingredients given in this description are indicated in terms of weight percentages on a 100% material basis unless otherwise noted.

Oxidizing Agent

The CMP formulation preferably includes at least one oxidizing agent for oxidizing metal in the substrate to its corresponding oxide, hydroxide, or ions (e.g., oxidizing copper to copper oxide). The resulting oxide layer is preferably formed along the entire wafer surface and tends to reduce the chemical etch and corrosion of low-lying metal regions on the wafer surface, which tends to prevent dishing that could otherwise result due to constant direct contact between the substrate surface and the reactive species in the polishing formulation. The formed oxide layer is abradable and can be removed by mechanical forces during polishing. It is theorized that the portions of this metal oxide layer are removed intermittently during polishing by mechanical abrasion from abrasive particles and/or secondary abrasion from the polishing pad, which temporarily exposes the substrate surface.

Some non-exclusive examples of oxidizing agents suitable for use in the present invention include peroxides, alkyl hydroperoxides, persulfates, periodates, chlorates, perchlorates, nitrates, and permanganates. Hydrogen peroxide, urea-hydrogen peroxide, potassium persulfate, and ammonium persulfate are preferred oxidizing agents. In an embodiment of the invention, the oxidizing agent is reduced during polishing to form a more powerful oxidizing agent such as a hydroxyl radical.

The oxidizing agent preferably makes up less than about 10% of the composition by weight, more preferably between about 1% and about 5%, and more preferably still between about 2% and about 4%.

Water

The CMP formulation can be an aqueous solution or slurry made up of 80-99% water and preferably contains at least about 90% water. The water is preferably de-ionized water having a quality of greater than about 18 mega Ohms.

Passivating Agent

In some systems, the oxide layer formed by the oxidizing agent during the chemical attack on the substrate surface is inadequate, by itself, to provide sufficient protection to low-lying metal regions on the wafer surface. The absence of an adequate passivation layer can result in severe dishing, high abrasion, and subsequent dissolution of the unprotected metal surface. For example, it is believed that some types of Cu (I) and Cu (II) oxide layers are relatively porous, which can allow the CMP formulation pass through the pores and cause an undesired amount of dissolution of the underlying copper on the wafer surface.

The CMP formulation of the present invention optionally includes a passivating agent to aid in forming a passivation layer of metal oxide on the surface of the substrate. The passivating agent acts as a corrosion inhibitor to protect the underlying metal regions of the substrate while allowing abraded material to be removed from the substrate surface as a soluble metal complex. Passivation of the substrate surface tends to prevent wet etching of the substrate surface that could result in dishing, corrosion, or erosion. The passivating agent is preferably capable of passivating the entire metal surface to be protected without a substantial reduction in the material removal rate during polishing.

Non-exclusive examples of passivating agents suitable for use in the CMP formulation include benzotriazole (“BTA”), napthyltriazole, corresponding thiols, and any other compounds that exhibit strong adsorption characteristics toward the metal surface to be polished. The passivating agent (when present) preferably makes up less than about 2% of the composition by weight, more preferably between about 0.1% and about 1%, and more preferably still between about 0.1% and about 0.5%.

Complexing Agent

The CMP formulation optionally contains a complexing agent that is capable of complexing (e.g., chelating) with the metal abraded from the substrate surface. In some systems, the formed complex catalyzes the decomposition of the oxidizing agent to form a stronger oxidizing species. Specifically, it has been shown that a water-soluble copper complex that is formed in this manner can enhance the catalytic decomposition of hydrogen peroxide to form a hydroxyl radical (*OH), which is a stronger oxidizing agent than the hydrogen peroxide. For example, glycine is believed to form a complex with copper ions that are liberated from the copper surface during polishing, and the glycine-copper complex catalyzes the decomposition of hydrogen peroxide. The attack of the copper surface by a hydroxyl radical significantly increases the copper removal rate from the surface of the substrate. The static dissolution rate of copper is also closely correlated with the hydroxyl radical concentration. Therefore, the kinetics of hydroxyl radical formation are believed to have a direct correlation with the material removal rate of copper during polishing, which can be controlled by controlling the rate of decomposition of the oxidizing agent through the addition of complexing agent.

The material that is abraded from the substrate surface is preferably at least partially solubilized in the CMP formulation to create soluble complexes that are removed as the formulation is passed across the wafer. The complexing agent may also accelerate the dissolution of small metal (e.g., copper) or metal oxide particles abraded from the wafer surface, which tends to prolong the life of the polishing pad, stabilize the material removal rate, and effectively reduce surface scratches.

The material removal rate tends to increase with increasing concentration of the complexing agent and decrease as the concentration of the passivation agent increases. Therefore, the amount of complexing agent included in the formulation is preferably balanced against the amount of passivating agent that is present to achieve an optimal balance of passivation and abrasion of substrate due to oxidation.

The complexing agent (when present) preferably makes up less than about 5% of the composition by weight, more preferably between about 0.1% and about 3%, and more preferably still between about 0.5% and about 2%.

Bifunctional Agent

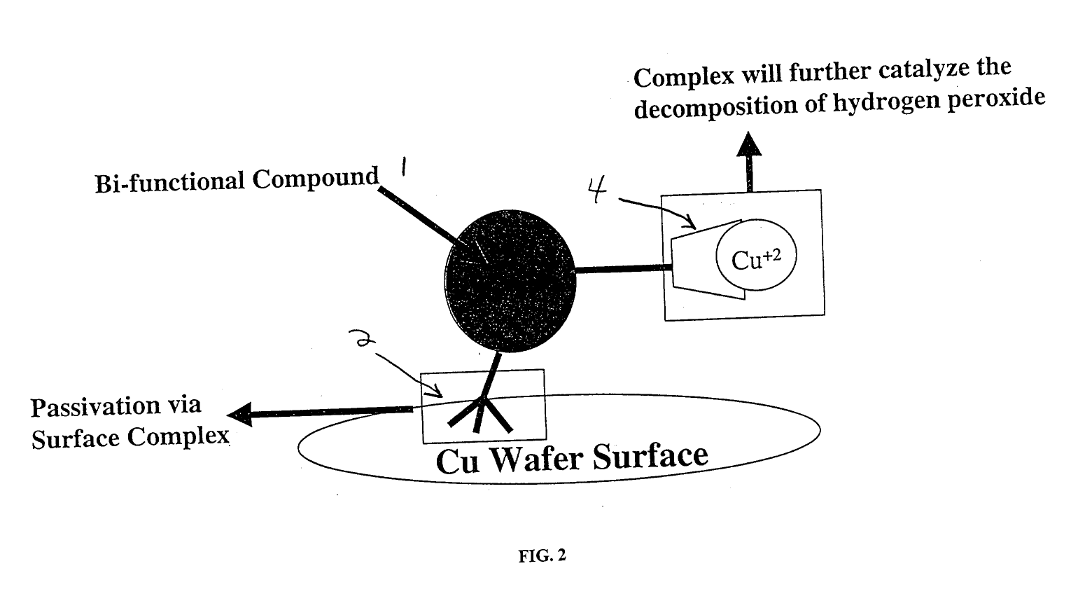

The CMP formulation optionally includes a bifunctional agent having two functional groups to enable it to function as both (or either) a passivating agent to inhibit corrosion and a complexing agent to decompose the oxidizing agent. It is desired that the bifunctional agent have sufficient passivation and catalytic characteristics to increase the efficiency of the polishing pad that provides the abrasive force to remove the generated thin film. The bifunctional agent preferably (i) allows for surface complexation to protect the low-lying metal (e.g., copper) regions and reduce dishing and erosion; and (ii) has the necessary catalytic functionality to aid in the decomposition of the oxidizing agent to produce a desired radical species for film attack to facilitate the removal of material from the substrate. As pictorially depicted in FIG. 2, a first functional group 2 of the bifunctional agent 1 is capable of functioning as a passivation agent by aiding in the formation of a passivation layer on the substrate surface. A second functional group 4 of the bifunctional agent has catalytic functionality to catalyze the decomposition of the oxidizing agent (e.g., hydrogen peroxide) into a stronger oxidizing species (e.g., hydroxyl radicals).

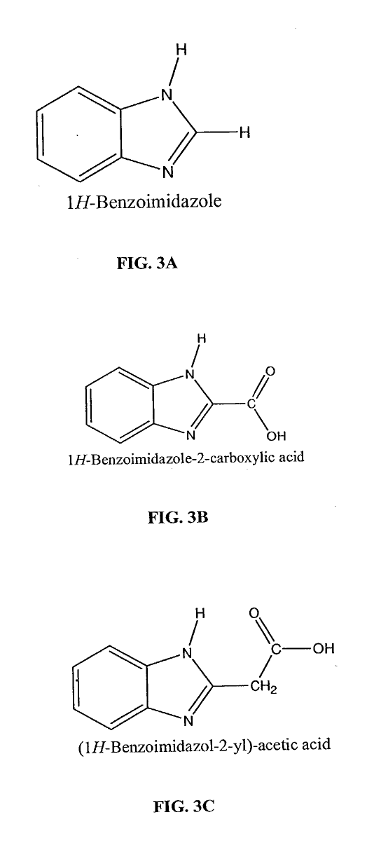

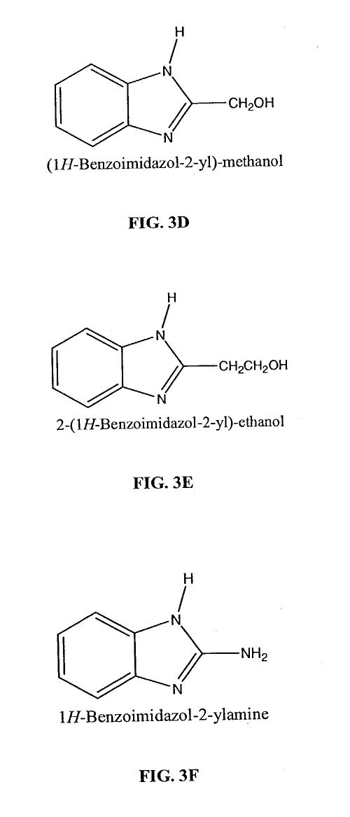

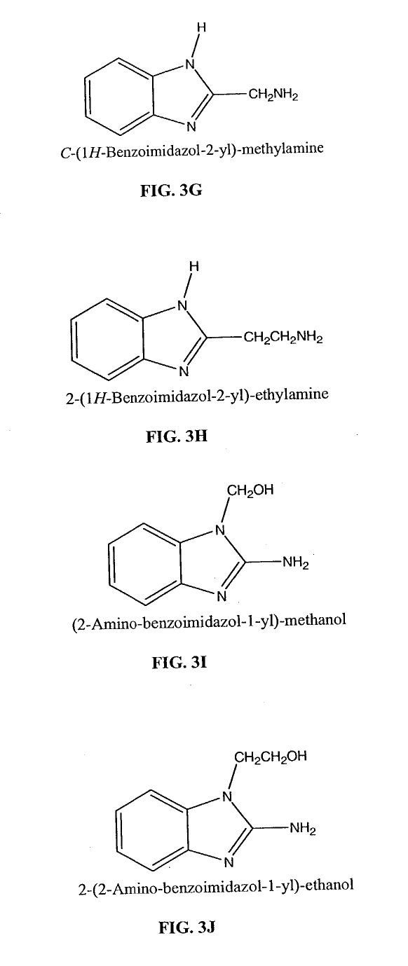

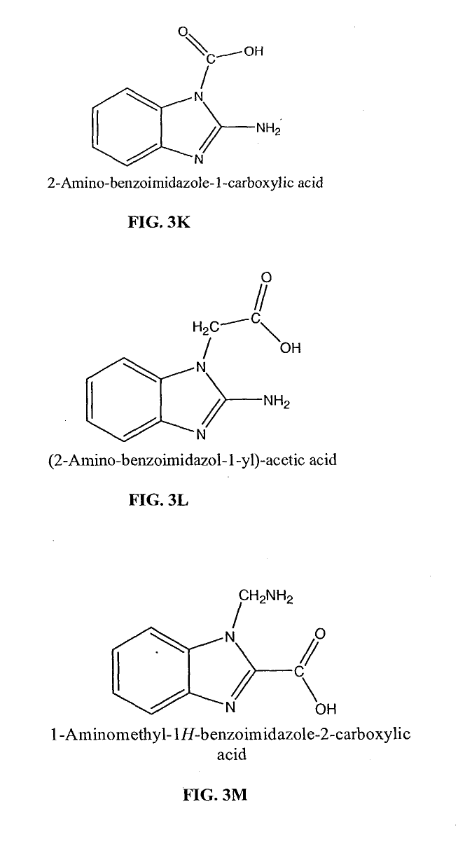

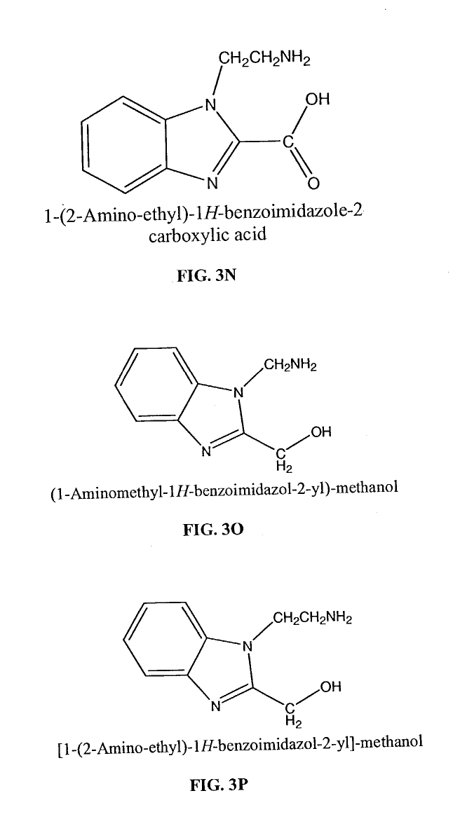

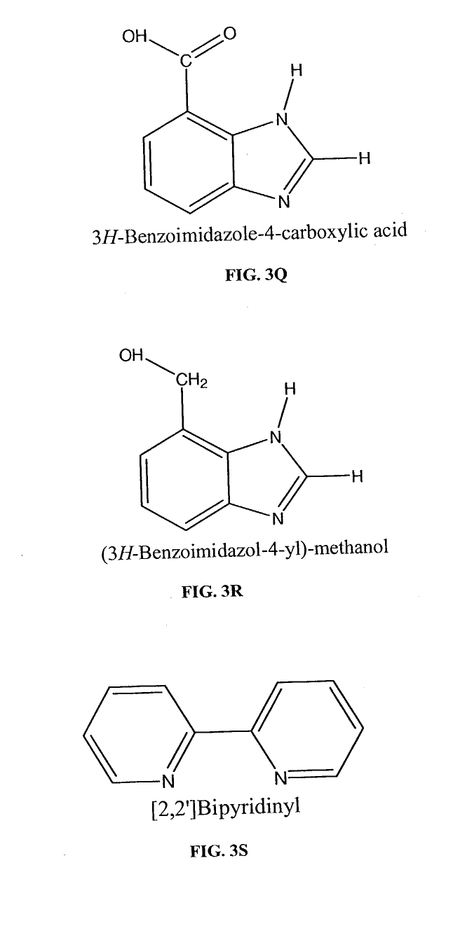

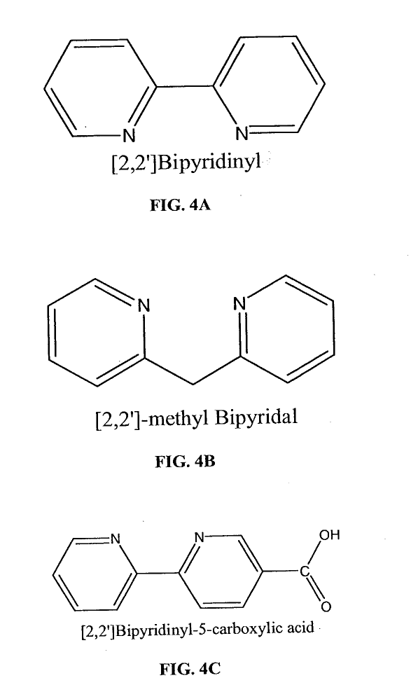

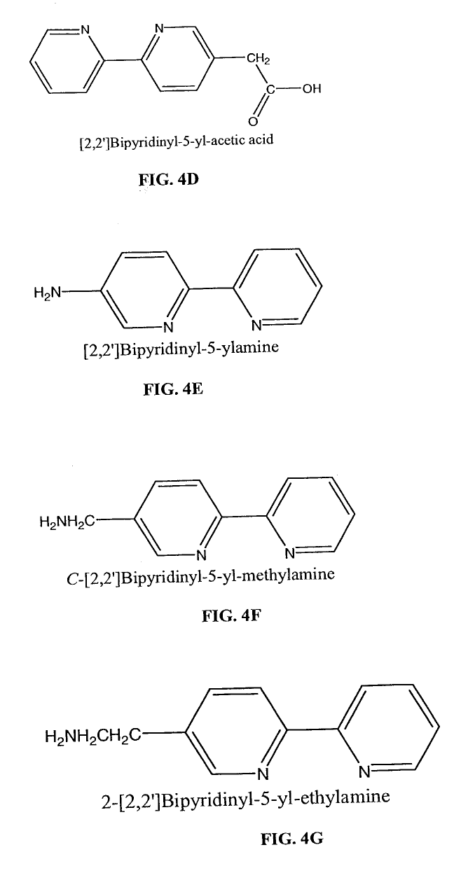

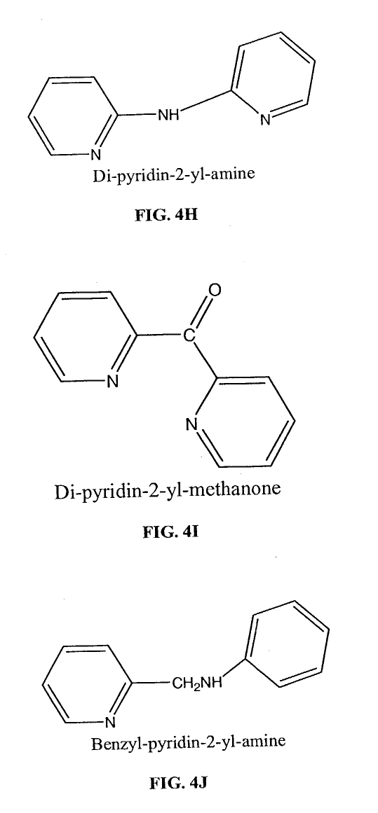

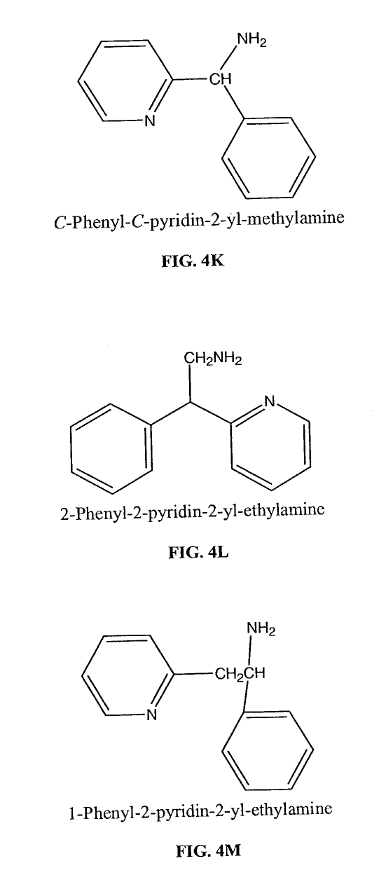

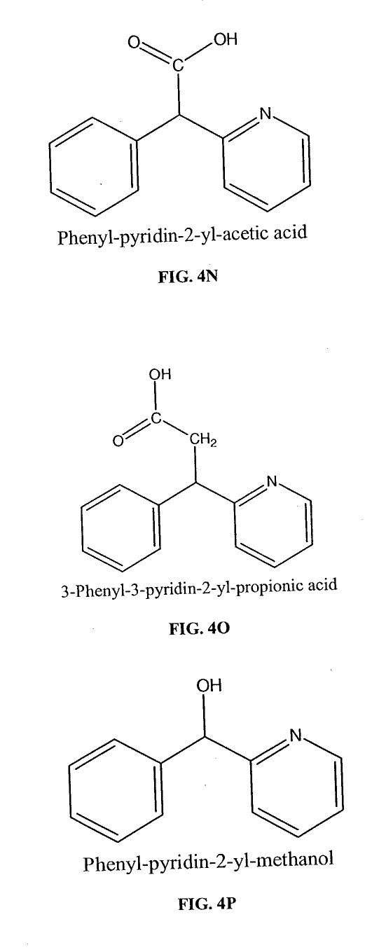

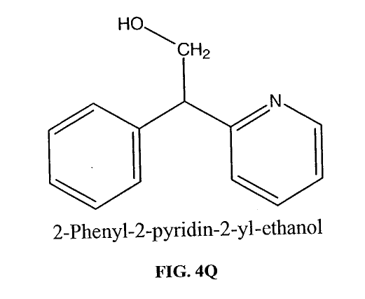

Nonexclusive examples of suitable bifunctional agents that can be used in the CMP formulation include imidazole, benzimidazole, bipyridyl, and derivatives thereof. Non-exclusive examples of benzimidazole-based derivatives suitable for use in the CMP formulation are depicted in FIGS. 3A to 3S. Non-exclusive examples of bipyridyl-based derivatives suitable for use in the CMP formulation are depicted in FIGS. 4A to 4Q. The bifunctional agent may be purified by, e.g., recrystallization before being added to the CMP formulation.

The concentration of the bifunctional agent (when present) in the composition is preferably less than about 200 mM, more preferably between about 1 mM and about 100 mM, and more preferably still between about 10 and about 60 mM.

Excess Metal Ions

In one embodiment of the invention, excess metal ions (e.g., copper (II) or iron (III) ions) are added to the composition (prior to use) to increase the number of pre-polish catalytic complexes that are formed. The initial concentration of Cu²⁺ in the composition is preferably between about 10 ppm and about 2000 ppm, more preferably between about 20 ppm and about 1000 ppm, and more preferably still between about 50 ppm and about 400 ppm. It is believed that including excess metal ions in the composition will increase the material removal rate and “prime” the system at the inception of polishing by accelerating the formation of the metal complex that is believed to catalyze the decomposition of hydrogen peroxide. The metal ions may also be contained or entrapped in a supramolecular aggregation species as described below.

Supramolecular Structures

Supramolecular structures may be formed in, or added to, the CMP formulation in order to increase polishing performance and efficiency. Such supramolecular structures include, e.g., micelles, vesicles, liposomes, polymeric shells, and any other colloidal structures or encapsulants capable of isolating and reversibly entrapping, or solubilizing, an active agent in the formulation (e.g., a copper complex, bifunctional agent, etc.) and then subsequently releasing the active agent during polishing.

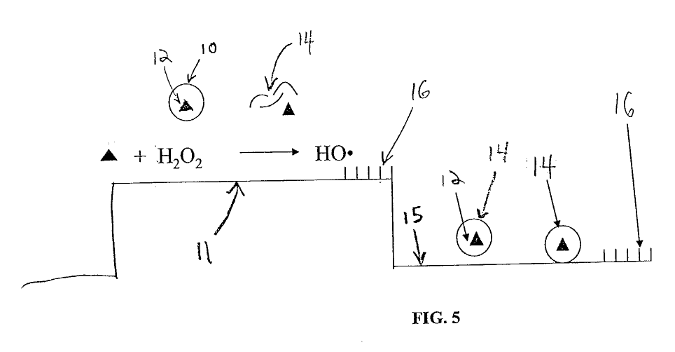

Without intending to be bound to a particular theory, FIG. 5 pictorially illustrates how supramolecular structures can be used to isolate, and then selectively release, an active agent to accelerate polishing at selected areas of the substrate. In the system depicted in FIG. 5, the active agent 12 is a catalytic agent that is trapped or isolated in a soft organic supramolecular structure 10 that is capable of releasing the catalytic functionality or reagent to a targeted surface upon demand. In this example, the active agent 12 is capable, upon being released, of catalyzing the decomposition of hydrogen peroxide to form hydroxyl radicals. When the supramolecular structure is a micelle, it is believed that the active agent is isolated by being solubilized by the micelle. On the other hand, when the supramolecular structure is a vesicle, it is believed that the active agent is isolated by encapsulation within the core formed by the vesicle as shown in FIG. 5.

The “demand” for the active agent is preferably signaled by the forces exerted on the substrate by the polishing pad during use, which can increase the local temperature and pressure in the vicinity of the protruding surfaces 11 of the substrate to disrupt (e.g., increase the permeability of) or rupture the supramolecular structures in those areas and expose the active agent to the protruding surfaces. The disturbed or ruptured supramolecular structure is indicated by molecule 14. A relatively high local pressure near the protruded areas 11 of the substrate can “turn on” the catalytic functionality to provide a relatively high material removal rate, while the lower pressures in the lower-lying or dished areas 15 of the substrate tend to prevent or inhibit release of the active agent from the supramolecular structures 14 in those areas. As a net result, the material removal rate in the dished area will be minimized and planarization efficiency will increase.

For example, when pressure is applied at the protruded area and/or when the local temperature is changed due to frictional forces from the polishing pad, the active agents 12 located in the vicinity of protruded areas of the substrate are preferably released and exposed to the protruded areas to promote local catalytic action that increases the material removal rate at those areas, which tends to increase planarization efficiency. On the other hand, the encapsulated active agents 12 are believed to be practically inert when isolated within the supramolecular structures in the low-lying areas of the substrate as shown in FIG. 5.

The system depicted in FIG. 5 also may include a passivating agent or complexing agent such as benzotriazole (“BTA”) or benzimidazole (a bifunctional compound) to create a passivation film 16 in order to control corrosion, protect any dished areas, and help regulate the material removal rate. Both the oxidizing agent and passivating agent can be encapsulated or freely dissolved in the continuous phase of the formulation.

Copolymer Enhancement Agent

It has been found that certain types of copolymer enhancement agents can be used in CMP formulations to enhance polishing performance by increasing the material removal rate and planarization efficiency. The copolymer enhancement agent has been found to have synergistic polishing effects when combined with the bifunctional agent in a CMP formulation.

In an embodiment of the invention, the enhancement agent is a block copolymer with a backbone having adjacent functional groups that have alternating polarities in water. For example, the enhancement agent may be a block copolymer of the form A-B-A, wherein “A” represents a functional group having hydrophilic properties and “B” represents a functional group having hydrophobic properties. Alternatively, “A” could be a hydrophobic functional group while “B” is a hydrophilic group. The block copolymer is preferably capable of aggregating in an aqueous solution to form a supramolecular structure such as a micelle.

One exemplary category of copolymer enhancement agents that has been found to be suitable for use in the present invention is polyoxyalkylene block copolymers. The polyoxyalkylene block copolymer may be of the form A_{α}B_{β}A_{α′}, where A and B are alkylene oxide monomers such as ethylene oxide, propylene oxide, or butylene oxide, and where A and B are different monomers with different polarities. In one embodiment, the copolymer is a tri-block copolymer of polyethylene oxide and polypropylene oxide having the general formula HO(CH₂CH₂O)_{α}(CH(CH₃)CH₂O)_{β}(CH₂CH₂O)_{α′}H, where α and α′ are integers between about 2 and about 140 and β is an integer between about 50 and about 75. That is, the propylene oxide (PO) block is sandwiched between two ethylene oxide (EO) blocks as follows: EO-PO-EO. Alternatively, the copolymer may be a triblock copolymer of the form PO-EO-PO, wherein the ethylene oxide block is sandwiched between two polypropylene blocks.

Nonexclusive examples of suitable tri-block copolymers include the Pluronics® family of compounds commercially available from the BASF Corp. of Mount Olive, N.J. Pluronic® P103, P104, P105, P123, F108, F88, Li01, and L121 are suitable copolymers for use in the present invention. The Pluronic® R family of compounds may also be used. The Pluronic® and Pluronic® R families of compounds are collectively referred to herein as “pluronic compounds.” The poly(ethylene oxide) and poly(propylene oxide) chains in pluronic compounds generally have relatively low reactivity, however, weak interactions between these chains and the metal substrate surface may occur through the ether (C—O—C) links or through the terminal hydroxyl groups. The pluronic compounds have surface active agent properties because the poly(ethylene oxide) group has a hydrophilic (“water-loving”) nature while the poly(propylene oxide) has a hydrophobic (“water-fearing”) nature.

It is anticipated that additional block, random, and/or random-block copolymers that have chemical properties similar to pluronics compounds would be suitable copolymer enhancement agents, including certain triblock copolymers of the Synperonice Series available from Uniqema Inc., as well as similar copolymers available from The Dow Chemical Company of Midland, Mich. such as EP Series Block Copolymers, SYNALOX® EPB Random Copolymers, and SYNALOX® PB Series polyoxyalkylene copolymer.

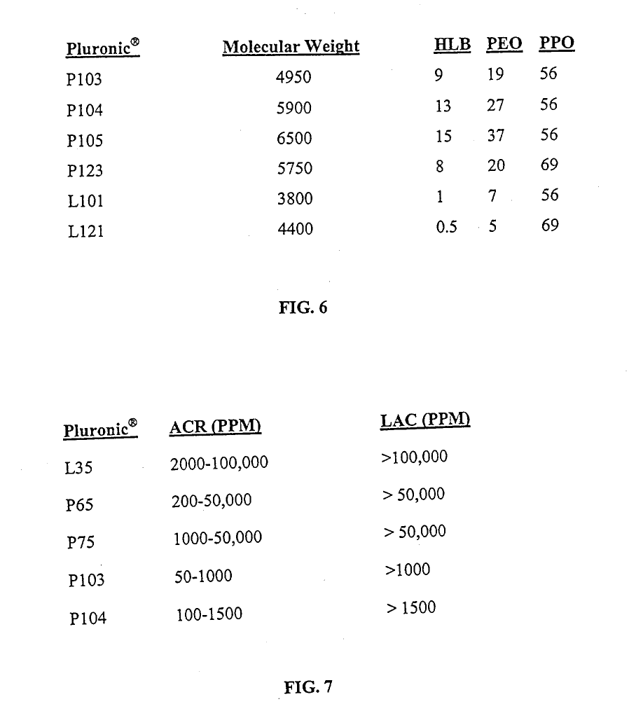

The hydrophile-lipophile balance (“HLB”) is a useful way to distinguish pluronic compounds, and a table summarizing various physical properties for exemplary pluronics compounds applicable to the present invention is presented in FIG. 6. The HLB value may range from 0 (most lipophilic) to 20 (most hydrophilic), and the preferred range for copolymers suitable for use in the present invention is about 5 to about 15.

Pluronic® surfactants, unlike conventional nonionic surfactants, do not micellize at a critical micelle concentration (“CMC”). Instead, aggregation occurs over a broad concentration range that is referred to as the aggregation concentration range (“ACR”). The limiting aggregation concentration (“LAC”) is the point at which the surfactant reaches saturation, which would correspond to the more conventional CMC. The ACRs and LACs for pluronic compounds tend to occur at much higher orders of magnitude (e.g., greater than about 1,000 ppm) than for classical nonionic surfactants (which are commonly below 100 ppm). A table including aggregation concentration range (“ACR”) data and limiting aggregation concentration (“LAC”) data for exemplary Pluronic® copolymers is provided in FIG. 7.

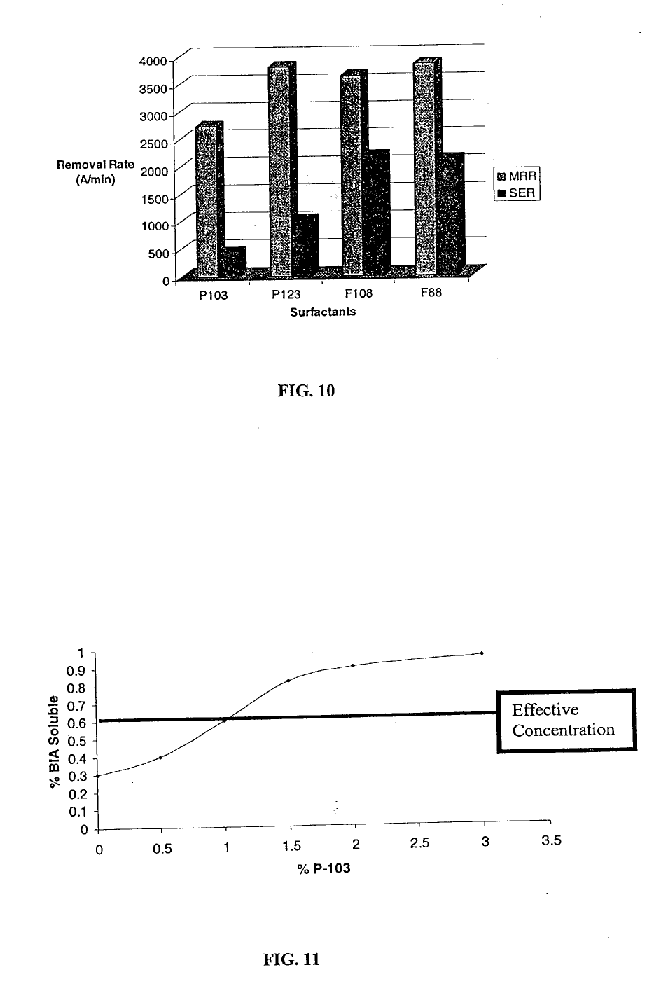

FIG. 10 contains a chart summarizing the material removal rates and static etch rates that were achieved using four exemplary AF Cu CMP formulations to polish a 1 inch copper disk. Each formulation contained benzimidazole, hydrogen peroxide, and a different Pluronic® surfactant. The exemplary Pluronic® surfactants (P103, P123, F108, and F88) were selected based upon their hydrophobic chain lengths and their overall wettability on a hydrophobic surface. It is theorized that one factor accounting for the differences in static etch rate among the formulations is the relative strength of the micelles formed by each Pluronic® that increase the solubility of the benzimidazole. It is believed that the relatively low static etch rate achieved with the Pluronic® P103-containing formulation occurred because micelles formed by P103 were of sufficient strength to inhibit the release of at least some of the benzimidazole in the lower-lying areas of the substrate.

FIG. 11 contains a graph showing the results of a solubility study to investigate the presence of micelles in a CMP formulation that contains benzimidazole (BIA). The x-axis indicates the concentration of P103 in the formulation in weight percent, and the y-axis indicates the concentration of soluble BIA in the formulation in weight percent. The graph shows that, for one exemplary formulation, the solubility of the BIA initially increased as the concentration of P103 increased. The increase in BIA solubility leveled off once the P103 concentration exceeded about 1.5-2%. Adding too much of the copolymer enhancement agent may alter the inherent solution properties (viscosity) of the formulation and reduce its effectiveness. The optimum amount of copolymer enhancement agent may vary among formulations and can be determined experimentally for a given system by one of ordinary skill having the benefit of this Specification. For the formulation depicted in FIG. 11, it was determined that a concentration of about 1% P103 was effective and resulted in the formation of micelles containing a benzimidazole core.

The copolymer enhancement agent preferably has a number-average molecular weight (Mn) greater than about 500, more preferably between about 1,000 and about 8,000, and more preferably still between about 3,500 and about 7,000. The copolymer enhancement agent (when present) preferably makes up less than about 10% of the composition by weight, more preferably between about 0.1% and about 7%, and more preferably still between about 1% and about 5%. The copolymer enhancement agent may be purified by, e.g., ion-exchange before being added to the CMP formulation.

Micelles

The CMP formulation may contain a micelle-forming agent that forms micelles in the solution when present in an amount at or greater than the critical micelle concentration. Nonexclusive examples of micelle-forming agents includes cationic surfactants, anionic surfactants, nonionic surfactants, and various combinations thereof. The micelle-forming agent preferably is an amphipathic surfactant molecule capable of forming nonionic surfactant micelles. The copolymer enhancement agent is preferably capable of acting as a micelle-forming agent in the CMP formulation and is preferably included in the formulation in an amount that is at or above the critical micelle concentration (or limiting aggregation concentration) to cause micelle formation prior to polishing. Without intending to be bound to a particular theory, the copolymer enhancement agent is believed to form micelles that solubilize the bifunctional agent to isolate it in the solution prior to polishing.

In aqueous solutions, the copolymer chains contained on the above-described pluronic compounds are believed to form spherical micelles characterized by the formation of the hydrophilic polyethylene oxide strands on the outside (corona) and the hydrophobic polypropylene oxide segments on the inside (core). The spherical micelles can be used to substantially solubilize chemically-reactive active agents (e.g., passivating agents, complexing agents, bifunctional agents, etc.) by surrounding them to increase their solubility in the CMP formulation, which tends to limit or control the amount of active agent that is in contact with the substrate at a given time.

The formed micelle can be disrupted by applied pressure, e.g., the downward force applied to the wafer as it contacts the polishing pad, to release the copolymer and bifunctional agent onto the topographical high points of the substrate. This preferably selectively occurs at high points on the substrate where the applied pressure is at a maximum. The bifunctional agent may then act to passivate the metal surface and coordinate the abraded metal oxides to generate an oxidation activating metal salt to further catalyze the decomposition of the oxidizer on the surface to be polished. The copolymer enhancement agent is therefore preferably capable of serving two main functions: (i) solubilizing the bifunctional agent by micellization, and (ii) facilitating the pressure-induced release of this agent to the surface of the substrate. In this manner, the rate of application of the active agent is increased in selected areas of the substrate to increase planarization efficiency.

Vesicles

Vesicles may be used to isolate reactive species in the formulation by encapsulation. In one embodiment of the invention, vesicles are utilized as an extension of the micellar model for pressure-induced release of the oxidation activator. Vesicles can be formed from synthetic amphipathic or phospholipid materials by modifying the phase diagram through the addition of a hydrotrope and dilution of the micellar phase. The hydrotrope is preferably a water-soluble, amphiphilic molecule that lacks sufficient lipophilicity to act as a surfactant and increases the aqueous solubility of various slightly soluble organic chemicals without the formation of micelles or microemulsions. Exemplary hydrotropes include benzene sulfonate salts (such as sodium benzene sulfonate), monohydroxy-substituted benzene sulfonate salts, dihydroxysubstituted benzene sulfonate salts, benzene disulfonate salts (such as sodium benzene disulfonate), toluene sulfonate salts (such as sodium p-toluene sulfonate), bromobenzene sulfonate salts (such as sodium p-bromobenzene sulfonate), xylene sulfonate salts (such as sodium xylene sulfonate), mixtures thereof, as well as corresponding salts formed from cations such as potassium, lithium, ammonium, alkylammonium, and the like.

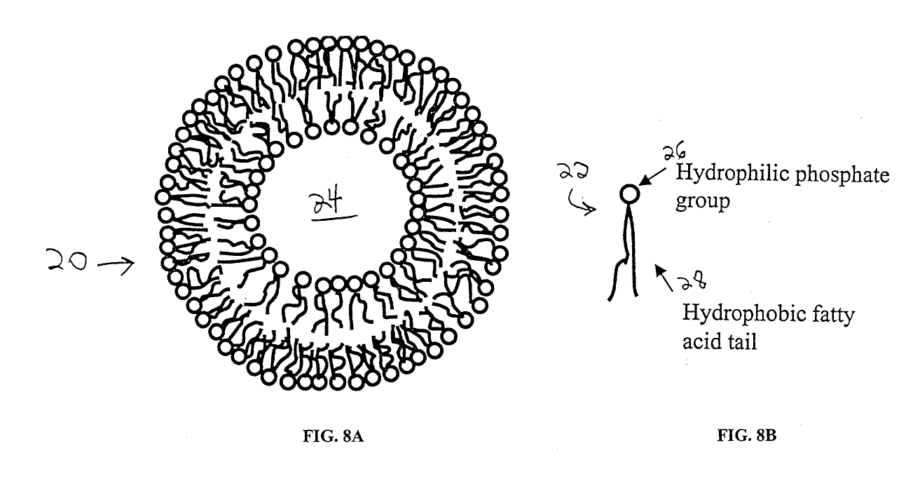

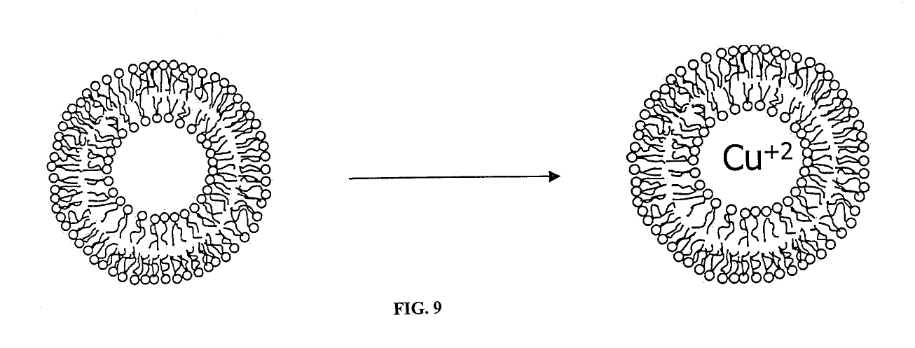

A vesicle formed from phospholipids is referred to herein as a “liposome.” An exemplary liposome 20 composed of a lipid bilayer is depicted in FIG. 8A. The lipids 22 forming the bylayer have a head 26 made up of a hydrophilic phosphate group and a hydrophobic fatty acid tail 28 as shown in FIG. 8B. At sufficient concentration in an aqueous solution, the lipids will spontaneously arrange into a spherical structure that includes one or more bylayers as depicted in FIG. 8A. The liposome includes a core 24 that may contain an active agent to reversibly isolate it from the substrate or other components in the CMP formulation. For example, a liposome can be used to encapsulate copper ions as shown in FIG. 9 by diluting a micellar phase with a solution of copper nitrate as described below.

The vesicles form an aqueous core and each vesicle preferably ranges from about 10 nm to about 100 μm in diameter, and more preferably less than about 500 nm. Vesicles can be used to encapsulate and isolate reactive reagents for controlled delivery to a reactive environment by using various physical or chemical means to release the encapsulated materials.

Vesicles can be produced by carefully diluting a hydrotrope/polymer solution with water and controlling mixing. Specifically, the vesicles in one embodiment of the invention are generated from mixing a solution containing 30% by weight of sodium xylenesulfonate, 10% lecithin, and 60% water until clear. This mixture can then be stirred with a copper (II) nitrate solution for 4-5 hours to induce encapsulation of the copper ion. Any remaining un-encapsulated copper (II) can be removed by dialysis. The dialysis process is conducted by combining the vesicle solution and de-ionized water into a dialysis tube and immersing the sealed tube in a reservoir of deionized water. The vesicle water mixture in the dialysis tube is mixed every few minutes to maintain sample homogeneity. The water in the reservoir is continuously stirred and replaced with fresh water every 8 minutes. Any unencapsulated ions can be removed from the formulation during this purification step. Techniques that can be used to increase the efficiency of the purification step include (but are not limited to) cross-flow filtration, cross-flow dialysis, and capillary dialysis.

The vesicle particle size can be adjusted by controlling the amount of sodium xylenesulfonate (“SXS”) that is added to the solution. The particle size will tend to decrease as more SXS is added. The liposomes preferably have a diameter that is less than about 100 nm. Alternatively, the vesicular phase may be generated by combining (i) a previously prepared exemplary clear vesicular stock phase containing 10% lecithin, 30% sodium xylenesulfonate, and 60% water with (ii) a sufficient amount of an aqueous solution and CMP formulation additives (e.g., oxidation activator, oxidizing agent, passivating agent, complexing agent, etc.) to form a CMP formulation. Proline and tryptophan have been found to be useful as complexing agents in vescicle-containing CMP formulations. The vesicles (when present) preferably make up less than about 10% of the CMP composition by weight, more preferably between about 1% and about 5%, and more preferably still between about 0.1% and about 2%.

It is anticipated that other methods for vesicle formation (e.g., thin film hydration, sonication) can be used to make vesicles suitable for use in the present invention. U.S. Pat. Nos. 4,089,801 and 6,475,517 each include background information on methods for making vesicles and liposomes and are incorporated by reference as if fully set forth herein.

The particle size of the encapsulant largely determines the stability and rigidity of the encapsulant wall. Smaller particles tend to have a more rigid and stable wall due to their curvature. On the other hand, larger particles tend to have a flatter interface that is more unstable (i.e., easily ruptured) due to “floppiness.” Additionally, smaller vesicles can fit into smaller spaces, which allows them to more easily fit into the relatively low-pressure, lower-lying areas of the substrate (e.g., in dished areas) that are further from the polishing pad. The increase in encapsulant stability due to smaller particle size is also believed to protect the encapsulant from prematurely releasing it contents, which allows a more uniform delivery of the active agent.

Surfactant

The CMP formulation can optionally include one or more surfactants, stabilizers, or dispersing agents to stabilize the composition and inhibit settling or flocculation of components in the formulation. If a surfactant is added to the formulation, it may be anionic, cationic, nonionic, zwitterionic, or amphoteric. Exemplary surfactants suitable for use in the present invention can be of the class of alkylated polyethylene oxide, alkylated cellulose, alkylated polyvinyl alcohol, alkyl carboxylic acid, or aryl carboxylic acid. The surfactant, stabilizer, or dispersing agent preferably makes up less than about 3% of the composition by weight, more preferably between about 0.1% and about 2%, and more preferably still between about 0.25% and about 0.75%.

Cosolvent

A co-solvent may be included in the composition to increase the solubility of other species in the composition. The co-solvent can be a protic solvent such an alcohol or polyol. Alteratively, the cosolvent may be an aprotic solvent such as a ketone sulfoxide, or hydrotrope (e.g., aryl sulfonates). For example, a short chain alcohol such as 2-propanol, a glycol such as ethylene glycol, or a polyol such as tetraethylene glycol may be included to solubilize the bifunctional agent. Certain small ketones such as methyl butyl ketone can also enhance the solubility of less polar ingredients. Some hydrotropes such as sodium xylene sulfonate can form small aggregates that tend to solubilize less polar compounds. The cosolvent (when present) preferably makes up less than about 10% of the formulation by weight, and more preferably between about 3% and about 5% by weight.

Hydroxyl Radical Quencher

In some circumstances, the presence of high levels of hydroxyl radicals can cause undesirable corrosion of copper lines in the substrate during polishing. A hydroxyl radical quencher can optionally be used to reduce metal line corrosion. For example, it has been found that including about 5% or less by weight of ascorbic acid into a glycine-containing diamond slurry resulted in a noticeable decrease in copper line corrosion. It is believed that this decrease in corrosion was due to effective scavenging of the hydroxyl radical that was generated by the copper-glycine complex. A number of other hydroxyl radical quenchers can be employed (other than ascorbic acid) including, e.g., iodide compounds, carbonate compounds, 2-propanol, glycol compounds, 1,3-cyclohexadiene compounds, glycerine or glycerol compounds, tin hydride compounds, humic acids, azobenzene compounds, and unsaturated amines. The hydroxyl radical quencher (when present) preferably makes up less than about 5% by weight of the composition, more preferably between about 0.1% and about 3%, and more preferably still about 0.2% to 2%.

pH Adjustment Agent

The pH of the composition may be acidic or basic, depending upon the application, and will generally be in the range of about 3 to 11, and preferably in the range of about 4 to about 6.5. A pH adjustment additive may be included in the composition to adjust the pH to a desired value. Suitable pH adjustment agents include acids such as mineral acids (e.g., HCl, H₂SO₄, HNO₃, HI, etc.) or organic acids (e.g., formic acid, acetic acid, propanoic acid, oxalic acid, etc.). Suitable pH adjustment agents also include bases such as alkali and alkaline earth metal hydroxides and oxides (e.g., NaOH, NaO), ammonia, and organic amines.

The pH adjustment agent (when present) preferably makes up less than about 1% by weight of the composition, and more preferably between about 0.05% and about 0.5% depending on the desired final pH.

Abrasive Particles

The CMP formulation can optionally contain abrasive particles that are made of, e.g., alumina, silica, zirconium oxide, magnesium oxide, cerium oxide, or a mixed oxide. It has been found, however, that many of the formulations of the present invention are effective without the use of abrasive particles. It is therefore preferred that, for formulations to be used for polishing copper-containing substrates, the composition be substantially abrasive-free (i.e., contain substantially no abrasive particles) to minimize or eliminate problems such as dishing, erosion, microscratches, gross defects such as imbedded particles, rip outs, chatter marks, and delamination of the low-k or cap material. On the other hand, it is generally preferred (but not required) that the CMP formulation contains abrasive particles when it is to be used for polishing barrier materials such as tantalum, tantalum nitride, tungsten and other similar metals.

The following non-limiting examples illustrate several specific ways to make and use several embodiments of the present invention.

### EXAMPLE 1

The CMP formulation consisted of the following ingredients: 3% hydrogen peroxide, 0.59% benzimidazole, 1% Pluronic® P-103, 0.18% hydrochloric acid to give a solution pH of about 4.5 and deionized water as the remainder of the solution. This formulation was made by mixing the above-described amount of Pluronic® copolymer with deionized water and then stirring until the mixture became clear. The benzimidazole was then added slowly to this solution with stirring. The requisite amount of 30% hydrogen peroxide was then added to the solution to produce a 3% hydrogen peroxide concentration in the final formulation. The pH was then adjusted to 4.5 by adding 0.48% of 37.5% HCl.

This CMP solution was then used to polish a blanket copper film stack built on an 8 inch silicon wafer consisting of 15,000 Å electroplated copper on 250 Å Ta on 1000 Å oxide. The solution was also used to polish a patterned copper film stack consisting of ca. 15,500 Å of copper, 15,000 Å of which was electroplated on a 500 Å copper seed layer. Lying under the copper was 250 Å of a tantalum barrier on a dielectric stack of cap oxide on top of SiLK® low-k. The patterning on the wafers conformed to the 854 mask design. These wafers were obtained from SEMATECH in Austin, Tex. The polishing was conducted on a Westech 372M polisher under the following conditions: table speed (TS) of 90, carrier speed (CS) of 80, flow rate (FR) of 200 mL/min, down force (DF) of 4 psi, and an IC-1400 polishing pad. The removal rate using the above conditions was 3,600 Å/min, and the within wafer non-uniformity was (WIWNU) was 4.6%. The static etch rate of the abrasive-free polishing solution was less than 5 Å/min. The patterned wafer polishing results showed a surprisingly high planarization efficiency of 97.5% on a 100 μm×100 μm array (step height before polish is ca. 9500 Å) and dishing of only 500 Å at the endpoint and 700 Å after 25% overpolish (which is defined here as additional polishing time equal to 25% of total polish time to reach the endpoint). The rate of the above polishing solution was less than 10 Å/min on PETEOS silicon oxide, SiLK® low-k, and tantalum metal under-layers.

### EXAMPLE 2

The CMP formulation consisted of the following ingredients: 3% hydrogen peroxide, 1% proline, 1% lecithin vesicle with 135 ppm copper (II) ion encapsulated (with ppm on a total solution basis), and 5% colloidal silica abrasive, with the remainder being deionized water and a small amount of nitric acid to give a pH of 5.8. A vesicle stock solution was made by generating a clear solution having a composition of 10% lecithin, 30% sodium xylenesulfonate, and 60% water. This solution was shaken until it became clear and then was diluted 6-fold with deionized water containing 4000 ppm of a dissolved Cu(NO₃)₂ and then shaken for 4 hours to induce encapsulation. The remaining un-encapsulated copper ions were removed by placing the vesicle solution and deionized water (1:2 ratio) in a standard dialysis tube and submersing it into a four liter deionized water reservoir that was continuously re-circulated. The reservoir water was changed every 10 minutes and the dialysis solution was stirred every 5 minutes to maintain homogeneity. After the dialysis procedure, the vesicle size by dynamic light scattering was 103 nm and encapsulated copper was assayed as 314 ppm. A pH adjustment was made by adding a small amount of concentrated nitric acid to give a final solution pH of 5.8. Next, proline, hydrogen peroxide, and 140 nm diameter colloidal silica were added sequentially with stirring to form the final polishing solution of: 3% hydrogen peroxide, 1% proline, 1% lecithin vesicle containing 135 ppm Copper (II) ion encapsulated, and 5% colloidal silica abrasive at a pH of 5.8.

This CMP solution was used to polish a blanket tungsten film stack built consisting of a 6 inch silicon wafer substrate with 5000 Å CVD deposited tungsten on 250 Å Ti on 1000 Å silicon oxide. The solution was also polished on a patterned tungsten film stack consisting of ca. 5000 Å of tungsten, 250 Å of titanium barrier on silicon oxide dielectric. The patterned wafers were constructed using the 831 CMP mask design. These wafers were obtained from SEMATECH in Austin, Tex. The polishing was conducted on a Westech 372M polisher under the following conditions: table speed (TS) of 75, carrier speed (CS) of 65, flow rate (FR) of 190 mL/min, down force (DF) of 5 psi with 1 psi back pressure, oscillation speed of 2 mm/min and IC 1400 polishing pad with a SUBA IV sub-pad. The removal rate using the above conditions was 4700 Å/min, and the within wafer non-uniformity was (WIWNU) was 15.2%. The static etch rate of the abrasive-free polishing solution was less than 37 k/min. The static etch rate on an unencapsulated equivalent formulation would be expected to be about 100 Å/min. The patterned wafer results showed an average planarization efficiency of 74% on a 50 μm×50 μm array. The same chemistry without the vesicle encapsulation of the copper (II) oxidation activator showed only an average planarization efficiency of 55%.

Although various theories have been presented above to aid one of ordinary skill in the art to more fully appreciate the formulations of the present invention and the surprising and unexpected results obtained therethrough, it is to be understood that these theories should not be “read into” the claims below and do not limit the claims unless expressly recited therein.

What is claimed is:

1. A CMP formulation useful for polishing a semiconductor substrate, comprising:
water;
an effective amount of an oxidizing agent to facilitate polishing by promoting the removal of material from the substrate; and
a copolymer for enhancing polishing performance, comprising:
a first unit having a hydrophilic nature; and
a second unit located substantially adjacent to the first unit and having a hydrophobic nature.

2. The formulation of claim 1, further comprising a bifunctional compound having at least a first functional group and a second functional group, the first functional group being capable of inhibiting corrosion on the substrate during use, the second functional group being capable of forming a complex with material abraded from the substrate during use, the complex being capable of catalyzing decomposition of the oxidizing agent.

3. The formulation of claim 1, further comprising benzimidazole.

4. The formulation of claim 1, further comprising a bypyridal derivative compound.

5. The formulation of claim 1, further comprising a bifunctional compound selected from the group consisting of benzimidazole, an imidazole derivative, and a bypyridal derivative, and wherein the copolymer increases the solubility of the bifunctional compound in the formulation.

6. The formulation of claim 1, wherein the copolymer is a Pluronic® compound.

7. The formulation of claim 1, wherein the copolymer is a Pluronic® R compound.

8. The formulation of claim 1, wherein the copolymer is selected from the group consisting of Pluronic® P103, Pluronic® P123, Pluronic® F108, and Pluronic® F88.

9. The formulation of claim 1, further comprising an active agent that is chemically reactive with the substrate to enhance polishing performance, and wherein the copolymer is capable of forming a micelle during use that substantially solubilizes the active agent and subsequently releases the active agent upon the application of force during polishing.

10. The formulation of claim 1, wherein the oxidizing agent is hydrogen peroxide, and further comprising a complexing agent that is capable of forming a complex with material abraded from the substrate during polishing, the complex catalyzing decomposition of the hydrogen peroxide to form a hydroxyl radical during polishing.

11. The formulation of claim 1, further comprising an active agent that is chemically reactive with the substrate to enhance polishing performance, and wherein the copolymer forms a supramolecular structure that isolates the active agent from the substrate during use to control the rate of contact between the substrate and the active agent.

12. The formulation of claim 1, wherein the copolymer has a number average molecular weight between about 3,500 and about 7,000.

13. The formulation of claim 1, further comprising a bifunctional compound selected from the group consisting of benzimidazole, an imidazole derivative, and a bypyridal derivative, the bifunctional compound being present in the formulation in a concentration between about 1 mM and about 200 mM.

14. The formulation of claim 1, wherein the formulation is a non-abrasive solution that is substantially free of abrasive particles.

15. The formulation of claim 1, wherein the copolymer is a nonionic surfactant.

16. The formulation of claim 1, wherein the copolymer is a block copolymer of ethylene oxide and propylene oxide.

17. The formulation of claim 1, wherein the copolymer is a polyoxyalkylene block copolymer comprising hydrophilic and hydrophobic units.

18. The formulation of claim 1, wherein the copolymer is a tri-block copolymer of the form ABA, wherein A and B are blocks having substantially opposite polarities in water.

19. The formulation of claim 1, wherein the copolymer is a random copolymer comprising hydrophilic and hydrophobic units.

20. The formulation of claim 1, wherein the water makes up at least about 90% of the formulation by weight, the copolymer makes up between about 0.01% and about 5% of the formulation by weight, the oxidizing agent makes up between about 1% and about 5% of the composition by weight, and wherein the formulation has an acidic pH.

21. The formulation of claim 1, wherein the copolymer is present in a sufficient amount to form a micelle.

22. A CMP formulation useful for polishing a semiconductor substrate consisting essentially of:
water;
an oxidizing agent to facilitate polishing by promoting the removal of material from the substrate;
a polyoxyalkylene copolymer for enhancing polishing performance comprising a hydrophilic block and a hydrophobic block;
a bifunctional compound capable of inhibiting corrosion on the substrate during use; and
a pH adjustment agent.

23. A CMP formulation useful for polishing a semiconductor substrate, comprising:
water;
an active agent that is chemically reactive to enhance polishing;
a supramolecular structure capable of substantially isolating the active agent in the formulation, the supramolecular structure being further capable of releasing the reactive agent in response to a force applied against the substrate during polishing.

24. The formulation of claim 23, wherein the supramolecular structure is a micelle that substantially isolates the active agent by solubilizing it.

25. The formulation of claim 23, wherein the supramolecular structure is a vesicle that substantially isolates the active agent by encapsulating it.

26. The formulation of claim 23, wherein the supramolecular structure is a liposome.

27. The formulation of claim 23 wherein the active agent is selected from the group consisting of an oxidizing agent, excess metal ions, a complexing agent, a passivating agent, and a bifunctional agent.

28. The formulation of claim 23, further comprising an oxidizing agent.

29. A CMP formulation useful for polishing a semiconductor substrate, comprising:
water;
an effective amount of an oxidizing agent to facilitate polishing by promoting the removal of material from the substrate;
an active agent; and
a micelle capable of substantially solubilizing the active agent.

30. The formulation of claim 29, wherein the active agent is a bifunctional agent capable of inhibiting corrosion on the substrate and catalyzing decomposition of the oxidizing agent, and wherein the micelle is effective to enhance polishing performance by increasing planarization efficiency.

31. A CMP formulation useful for polishing a semiconductor substrate, comprising:
hydrogen peroxide, benzimidazole, a polyoxyalklyene copolymer, and water.

32. The CMP formulation of claim 31 wherein the polyoxyalkylene copolymer is a Pluronic® compound.

33. A method for making a CMP formulation useful for polishing a semiconductor substrate comprising:
mixing phospholipids, water, and a hydrotrope to form a solution;
adding an active agent to the solution;
forming vesicles in the solution;
agitating the solution to promote the encapsulation of the active agent within the vesicles; and
adding an oxidizing agent to solution.

34. The method of claim 33 wherein the active agent comprises metal ions.

35. A method for polishing a semiconductor substrate, comprising:
applying a CMP composition to the substrate, the CMP composition comprising an encapsulant forming a core and an active agent contained within the core;
applying a polishing force to the substrate; and
disturbing the encapsulant during polishing to release the active agent from the core, thereby causing a chemical reaction to enhance polishing of the substrate.

36. A method for polishing a semiconductor substrate, comprising:
applying a CMP composition to the substrate, the CMP composition comprising a micelle and an active agent that is substantially solubilized by the micelle;
applying a polishing force to the substrate; and
disturbing the micelle during polishing to release the active agent from the micelle, thereby causing a chemical reaction to enhance polishing of the substrate.

37. The formulation of claim 1, wherein the copolymer has an HLB number between about 5 and about 15.
